(19) United States
(12) Patent Application Publication
(10) Pub. No.: US 2007/0230258 A1
(43) Pub. Date: Oct. 4, 2007

(54) Semiconductor memory device for controlling bit line sense amplifying operation using row and column addresses

(76) Inventor: Dong Kyun Kim, Chungcheongbuk-do (KR)

Correspondence Address: LADAS & PARRY LLP, 224 SOUTH MICHIGAN AVENUE, SUITE 1600, CHICAGO, IL, 60604, US

(21) Appl. No.: 11/648,337

(22) Filed: Dec. 29, 2006

(30) Foreign Application Priority Data
Mar. 30, 2006 (KR) 10-2006-0029187

(51) Int. Cl. G11C 7/06

(52) U.S. Cl. 365/189.11; 365/203

(57) ABSTRACT

A semiconductor memory device includes a memory cell block for charging and discharging data into corresponding bit lines when an active command is inputted and any one of a plurality of word lines is enabled; a driving section for supplying a predetermined voltage to a pull-up node and a pull-down node by a column selection signal which is enabled when a read or write command is inputted; a sense amplifying section for sense amplifying a potential difference between a pair of bit lines by voltages supplied from the pull-up node and the pull-down node; a column address selecting section for transmitting data of the pair of bit lines amplified by the column selection signal, to a pair of input and output lines; and a precharge section for precharging the pair of bit lines by an equalizing signal which is enabled when a precharge command is inputted.

### CROSS-REFERENCE TO RELATED APPLICATIONS

The present application claims priority to Korean patent application number 10-2006-0029187 filed on Mar. 30, 2006, which is incorporated herein by reference in its entirety.

### BACKGROUND OF THE INVENTION

The present invention relates to a semiconductor memory device, and more particularly, to a semiconductor memory device that can independently control operations of a plurality of bit line sense amplifiers using low and column addresses.

In general, as shown in FIG. 1, a DRAM includes a driving unit 10, a plurality of bit line sense amplifiers 20, and a memory cell block 30. Each bit line sense amplifier 20 comprises a bit line equalizing section 21, a sense amplifying section 22 and a column address selecting section 23.

Among the operations of the DRAM configured in this way, a read operation will be described in detail with reference to FIGS. 1 and 2.

First, if an active command ‘Act’ is inputted as an external command, any one WLi of a plurality of word lines is enabled, and a fine potential difference is produced in the pair of bit lines BLT and BLB by the data stored in the memory cell block 30.

Also, the control signals SAN and SAP operate the driving unit 10 to raise the potential of the pull-up node CSP to the power source voltage level VDD and to lower the potential of the pull-down node CSN to the ground voltage level VSS.

When the potentials of the pull-up and pull-down nodes CSP and CSN are respectively raised to the power source voltage level VDD and lowered to the ground voltage level VSS, the sense amplifying section 22 is operated to sense-amplify the potential difference between the paired bit lines BLT and BLB.

Thereafter, when the pair of bit lines BLT and BLB is sufficiently amplified, a read command ‘Read’ is inputted from the outside, a column selection signal YS is enabled by the read command Read, and the data from the pair of amplified bit lines BLT and BLB is respectively transmitted to a pair of input and output lines IOT and IOB through the column address selecting section 23.

After the data sensed from the pair of bit lines BLT and BLB are amplified, the amplified data is respectively transmitted to the pair of input and output lines IOT and IOB, a precharge command ‘Precharge’ is inputted from the outside, resulting in the disabling of the enabled word line WLi and the control signals SAN and SAP while enabling the equalizing signal BLEQB.

At this time, the bit line equalizing section 21 is operated by the equalizing signal BLEQB and precharges the pair of bit lines BLT and BLB to the precharge voltage VBLP which corresponds to one half of the core voltage VCORE.

As can be readily seen from the above descriptions, in the DRAM, the procedure through which corresponding operations are implemented in response to the active command Act by the precharge command Precharge constitutes the basic cycle for accessing any one address. That is to say, the minimum cycle of the DRAM corresponds to an interval between directly after the input of the active command Act and immediately before the input of the next active command Act. This minimum cycle determines the speed performance of the DRAM.

However, in the above-described operations of the DRAM as shown in FIG. 1, if one word line WLi and the control signals SAN and SAP are enabled by the active command Act, because a number of the bit line sense amplifiers 20 corresponding to the enabled word line WLi are simultaneously operated, the amount of current flowing through the pull-up and pull-down nodes CSP and CSN increases, and the amount of current flowing through the driving unit 10 toward the lines having the power source voltage levels VDD and the ground voltage level VSS increases as well.

In other words, while not shown in FIG. 1, if one word line WLi and the control signals SAN and SAP are enabled, the number of simultaneously operated bit line sense amplifiers 20 ranges from several thousand to several tens of thousands.

Due to the presence of the simultaneously operated bit line sense amplifiers 20, voltage bouncing occurs in the pull-down node CSN and the line having the ground voltage level VSS, and a voltage drop occurs in the pull-up node CSP and the line having the power source voltage level VDD. As a consequence, a lengthy period is required until the pair of bit lines BLT and BLB is amplified to a sufficient CMOS level after the enabling of the control signals SAN and SAP; as a result, the possible input time of the read command Read is delayed.

Moreover, as the current consumed by the plurality of bit line sense amplifiers 20 in response to the active command Act significantly increases, the power consumption of the DRAM is adversely influenced.

### SUMMARY OF THE INVENTION

Accordingly, the present invention has been made in an effort to solve the above-mentioned and other problems occurring in the related art by providing a semiconductor memory device that can selectively drive a plurality of bit line sense amplifying sections using all of the row and column addresses of an active command and a read or write command, thereby decreasing operation speed delay and current consumption of the bit line sense amplifying sections.

According to one aspect of the present invention, there is provided a semiconductor memory device for sequentially implementing active, read or write, and precharge operations, comprising a plurality of sense amplifying sections for sense amplifying a pair of bit lines; and a plurality of driving sections operated by a column selection signal enabled upon the read or write operation, for independently controlling the pull-up and pull-down operations of the respective sense amplifying sections.

According to another aspect of the present invention, the active, read or write, and precharge operations are sequentially implemented upon the input of an outside compound command.

According to yet another aspect of the present invention, each driving section comprises a pull-up transistor, operated by the column selection signal, for supplying the power source voltage for the pull-up operation of each sense amplifying section; and a pull-down transistor operated by the column selection signal, for supplying the ground voltage for the pull-down operation of each sense amplifying section.

Still another aspect of the present invention provides a semiconductor memory device comprising a memory cell block for charging and discharging data into corresponding bit lines when an active command is inputted and any one of a plurality of word lines is enabled; a driving section for supplying a predetermined voltage to the pull-up node and the pull-down node through a column selection signal that is enabled upon the input of a read or write command; a sense amplifying section for sense amplifying the potential difference between a pair of bit lines by voltages supplied from the pull-up node and the pull-down node; a column address selecting section for transmitting the data from the pair of bit lines amplified by the column selection signal to a pair of input and output lines; and a precharge section for precharging the pair of bit lines by an equalizing signal that is enabled upon the input of a precharge command.

According to yet another aspect of the present invention, the active command, the read or write command, and the precharge command are sequentially inputted from the outside with a predetermined time interval.

According to still another aspect of the present invention, the driving section comprises a pull-up transistor operated by the column selection signal, which supplies the power source voltage to the pull-up node; and a pull-down transistor operated by the column selection signal, which supplies the ground voltage to the pull-down node.

According to a still further aspect of the present invention, the column address selecting section transmits data from the pair of amplified bit lines to the pair of input and output lines at the same time as when the sense amplifying section sense amplifies the potential difference between the bit lines.

### BRIEF DESCRIPTION OF THE DRAWINGS

The objects, and other features and advantages of the present invention will become more apparent after a reading of the following detailed description taken in conjunction with the drawings, in which:

FIG. 1 is a circuit diagram schematically illustrating a driving unit, a plurality of bit line sense amplifiers and a memory cell block in a conventional semiconductor memory device;

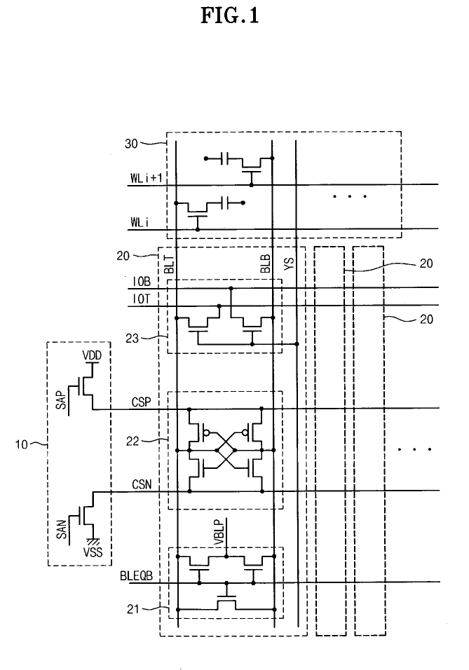

FIG. 2 is a waveform diagram for explaining a read operation in FIG. 1;

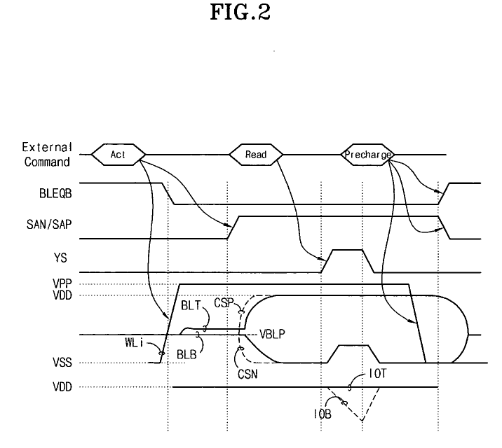

FIG. 3 is a circuit diagram schematically illustrating a plurality of bit line sense amplifiers and a memory cell block in a semiconductor memory device in accordance with an embodiment of the present invention; and

FIG. 4 is a waveform diagram for explaining a read operation in FIG. 3.

### DESCRIPTION OF SPECIFIC EMBODIMENTS

Reference will now be made in greater detail to a preferred embodiment of the present invention, an example of which is illustrated in the accompanying drawings. Wherever possible, the same reference numerals will be used throughout the drawings and the description to refer to the same or like parts.

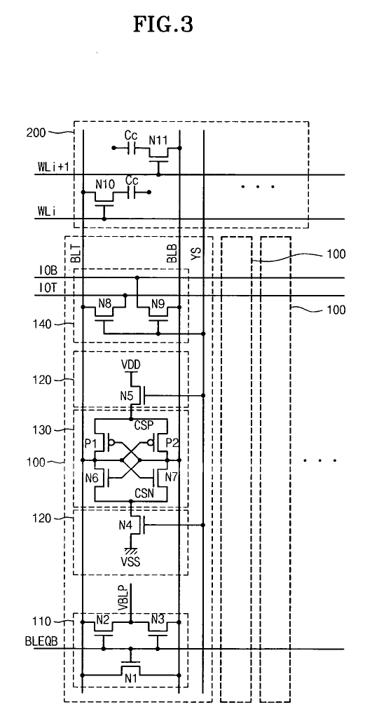

A circuit in accordance with en embodiment of the present invention is shown in FIG. 3. An embodiment of the present invention can be applied to a semiconductor memory device which uses a compound command, including an active command, a read or write command, and a precharge command. In this embodiment, the driving section 120, controlled by the column selection signal YS, is provided for the sense amplifying section 130 to sense amplify the potential difference between the paired bit lines BLT and BLB when the column selection signal YS is enabled.

Specifically, the embodiment shown in FIG. 3 comprises a plurality of bit line sense amplifiers 100 and a memory cell block 200. Each bit line sense amplifier 100, operated by the column selection signal YS, sense amplifies the potential difference between the paired bit lines BLT and BLB, transmits the amplified potential difference to a pair of input and output lines IOT and IOB, and precharges the paired bit lines BLT and BLB in response to the equalizing signal BLEQB to a level corresponding to the precharge voltage VBLP. The memory cell block 200 stores data.

Each bit line sense amplifier 100 comprises a precharge section 110, a driving section 120, a sense amplifying section 130, and a column address selecting section 140. The configurations of these parts will be described below in detail with reference to FIG. 3.

The precharge section 110 is composed of three NMOS transistors, N1 through N3, which are controlled by the equalizing signal BLEQB. Both terminals of one NMOS transistor N1 are connected to the pair of bit lines BLT and BLB. The first terminals of the two remaining NMOS transistors N2 and N3 are respectively connected to the pair of bit lines BLT and BLB, and the precharge voltage VBLP is supplied to the second terminals of the two remaining NMOS transistors N2 and N3.

The driving section 120 is composed of two NMOS transistors N4 and N5, which are controlled by the column selection signal YS. One terminal of the NMOS transistor N4 is connected to the pull-down node CSN, and the other terminal of the NMOS transistor N4 is connected to the ground voltage VSS line. Further, one terminal of the NMOS transistor N5 is connected to the pull-up node CSP, and the other terminal of the NMOS transistor N5 is connected to the power source voltage VDD line.

The sense amplifying section 130 is composed of two PMOS transistors P1 and P2 and two NMOS transistors N6 and N7, which are connected in the shape of a cross couple. The respective NMOS transistors N6 and N7 and the respective PMOS transistors P1 and P2 sense amplify the potential difference between the pair of bit lines BLT and BLB through the voltages supplied from the pull-up and pull-down nodes CSP and CSN.

The column address selecting section 140 is composed of two NMOS transistors N8 and N9, which are controlled by the column selection signal YS. The first terminals of the NMOS transistors N8 and N9 are connected to the pair of bit lines BLT and BLB, and the second terminals of the NMOS transistors N8 and N9 are connected to the pair of input and output lines IOT and IOB.

In the memory cell block 200, cells, each composed of one NMOS transistor (for example, N10) and one capacitor Cc, are alternately connected to the pair of bit lines BLT and BLB. When one word line (for example, WLi) is enabled, the data charged in the capacitor Cc of the corresponding cell is transmitted to the bit line BLT, or the data provided from the bit line BLT is charged to the capacitor Cc of the corresponding cell.

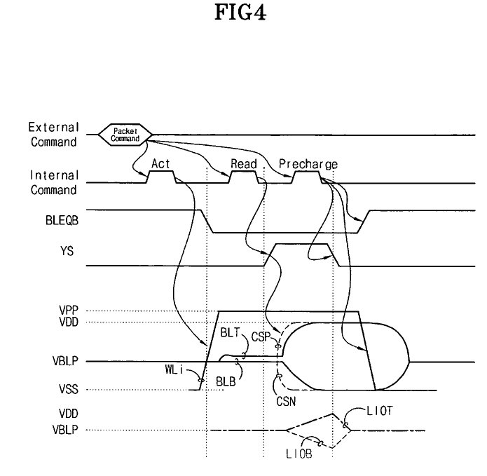

A read operation by a compound command, an operation of this embodiment of the present invention, will be described in detail with reference to FIGS. 3 and 4.

First, as a compound command, specifically a packet command ‘Packet Command’, is inputted as an external command ‘External Command’, an active command ‘Act’, a read command ‘Read’, and a precharge command ‘Precharge’ are sequentially and automatically inputted as internal commands ‘Internal Command’. At this time, the packet command is a command that is already set in an external interface such that the active, read or write, and precharge commands are sequentially inputted at a predetermined time interval.

As the active command Act is inputted by the packet command Packet Command, the equalizing signal BLEQB is disabled, and the pair of bit lines BLT and BLB are converted into a floating state. Further, when any one WLi of the plurality of word lines is raised to the pumping voltage VPP level, the NMOS transistor N10 of the memory cell block 200 is turned on, thereby inducing a fine potential difference between the pair of bit lines BLT and BLB.

Thereafter, as the read command Read is inputted, the column selection signal YS is enabled. According to this, the driving section 120 is operated, the potential of the pull-up node CSP is raised to the power source voltage VDD level, and the potential of the pull-down node CSN is lowered to the ground voltage VSS level.

Next, as voltages are supplied to the pull-up and pull-down nodes CSP and CSN, the sense amplifying section 130 is operated and sense amplifies the potential difference between the paired bit lines BLT and BLB. At the same time, the column address selecting section 140 transmits the potentials of the sense-amplified bit lines BLT and BLB to the pair of input and output lines IOT and IOB, respectively.

In other words, when the active command Act is generated, the column selection signal YS is enabled, driving section 120 and the column address selecting section 140 are simultaneously operated, and the data sense amplified by the sense amplifying section 130 is immediately transmitted to the pair of input and output lines IOT and IOB.

At this time, each driving section 120 is controlled by the column selection signal YS, similarly to the column address selecting section 140. The driving sections 120 with the same number as the sense amplifying sections 130 are respectively connected to the sense amplifying sections 130 and independently control the operations of the respective sense amplifying sections 130.

Thereupon, as the precharge command ‘Precharge’ is generated, the column selection signal YS is disabled, and the equalizing signal BLEQB is enabled. By the equalizing signal BLEQB, the precharge section 110 is operated and precharges the pair of bit lines BLT and BLB to the precharge voltage VBLP level.

As described above, in the embodiment of the present invention, one driving section 120 does not drive the plurality of sense amplifying sections 130; instead, one driving section 120, controlled by the column selection signal YS, drives one sense amplifying section 130.

Therefore, in this embodiment of the present invention, because a portion of the plurality of sense amplifying sections 130 can be selectively controlled using all of the row and column addresses corresponding to the read or write commands, the operation current of the semiconductor memory device can be decreased.

Further, when an embodiment of the present invention is applied to a semiconductor memory device using a compound command, upon the input of the read or write command, the sense amplifying operation is implemented, and the amplified data is simultaneously transmitted to the pair of input and output lines. Therefore, it is possible to decrease the time required for implementing corresponding operations from the active command to the read or write command.

As is apparent from the above description, in the present invention, because one driving section controlled by a column selection signal is correspondingly connected to one sense amplifying section, such that a portion of the plurality of sense amplifying sections can be selectively used, the current used in the operation of a bit line sense amplifier can be decreased.

Also, when the present invention is applied to a semiconductor memory device using a compound command, because the interval between directly after the input of an active command and immediately before the input of the next command is shortened, the semiconductor memory device can operate at a high speed.

Although a preferred embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A semiconductor memory device comprising:
a plurality of sense amplifying sections for sense amplifying a voltage between a pair of bit lines; and
a plurality of driving sections operated by a column selection signal which is enabled upon the read or write operation, for independently controlling pull-up and pull-down operations of the respective sense amplifying sections.

2. The semiconductor memory device of claim 1, wherein the active, read or write, and precharge operations are sequentially implemented as a compound command is inputted form the outside.

3. The semiconductor memory device of claim 1, wherein each driving section comprises:
a pull-up transistor operated by the column selection signal, for supplying a power source voltage for the pull-up operation of each sense amplifying section; and
a pull-down transistor operated by the column selection signal, for supplying a ground voltage for the pull-down operation of each sense amplifying section.

4. A semiconductor memory device comprising:
a memory cell block for storing data which is connected to a pair bit lines;
a driving section for supplying a predetermined voltage to a pull-up node and a pull-down node by a column selection signal;
a sense amplifying section for sensing and amplifying a potential difference between a pair of bit lines by voltages supplied from the pull-up node and the pull-down node;
a column address selecting section for transmitting the data amplified by the sense amplifying selection signal, to a pair of input and output lines; and
a precharge section for precharging the pair of bit lines by an equalizing signal which is enabled when a precharge command is inputted.

5. The semiconductor memory device of claim 4, wherein the active command, the read or write command, and the precharge command are sequentially inputted from the outside with a predetermined time interval.

6. The semiconductor memory device of claim 4, wherein the driving section comprises:
a pull-up transistor operated by the column selection signal, for supplying a power source voltage to the pull-up node; and
a pull-down transistor operated by the column selection signal, for supplying a ground voltage to the pull-down node.

7. The semiconductor memory device of claim 4, wherein the column address selecting section transmits data of the pair of amplified bit lines to the pair of input and output lines at the same time when the sense amplifying section sense amplifies the potential difference between the pair of bit lines.

8. The semiconductor memory device of claim 4, wherein the column selection signal is enabled when a read or write command is inputted.

9. A semiconductor memory device comprising:
a pair of bit lines;
a sense amplifier connected to the pair of bit lines;
a driving unit for supplying operation voltage to the sense amplifier in response to a column selection signal.

10. The semiconductor memory device of claim 9, wherein the operation voltage is an external voltage.
